(19) United States
(12) Patent Application Publication
(10) Pub. No.: US 2009/0087774 A1
(43) Pub. Date: Apr. 2, 2009

(54) COMPOSITIONS AND METHODS FOR WET LAMINATION OF PHOTOPOLYMERIZABLE DRY FILMS ONTO SUBSTRATES

(75) Inventors: SHINJI YU, Kanagawa-ken (JP); PEDRO GONCALO TEIXEIRA DIAS JORGE, Sao Paulo (BR)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E.I. du Pont de Nemours and Company, Wilmington, DE (US)

(21) Appl. No.: 12/179,717

(22) Filed: Jul. 25, 2008

Related U.S. Application Data
(60) Provisional application No. 60/966,299, filed on Aug. 27, 2007.

(51) Int. Cl. G03F 7/004

(52) U.S. Cl. 430/270.1

(57) ABSTRACT

The invention is directed to a lamination fluid useful in processes for wet laminating a photopolymerizable film onto circuit board panels or other substrates. The lamination system comprises 1) a dry film photoresist, 2) a laminate comprising i) copper ii) stainless steel iii) non metal on a surface, 3) a lamination fluid and 4) fluid application device on the laminates. The lamination fluid comprises water and a surface energy modification agent. The surface energy modification agent is present in a range between 0.0001and 3.0 moles/liter, and the pH of the fluid is between 3 and 11.

### FIELD OF THE INVENTION

The present invention relates generally to laminating a photopolymerizable dry film, sometimes called photoresist, onto a substrate. More particularly, the wet lamination processes and compositions of the present invention are directed to improved wet lamination fluid compositions and methods, resulting in improved photoresist performance.

### BACKGROUND OF THE INVENTION

When dry film photoresist is applied to a substrate:
1. unwanted air entrapment can occur, particularly when the lamination interface surface(s) is(are) irregular or otherwise non-planar; and
2. unwanted residual material (e.g., anti-tarnish residue, such as, when the substrate surface is copper or stainless steel) can hinder dry film adhesion,
   and if so, the end product can have a circuitry pattern having circuitry lines prone to unwanted breaks or other defects.

Broadly speaking, wet lamination processes (for applying photoresist dry film to copper laminate) are known. See for example, U.S. Pat. No. 4,976,817 to Correa et al. However, with each new generation of circuit board design, circuit patterns tend to become smaller and therefore less tolerant to air entrapment and unwanted surface residuals. A need therefore exists for a wet lamination system for dry film photoresist with improved performance, particularly with respect to unwanted air entrapment and unwanted surface residue.

### SUMMARY OF THE INVENTION

The present invention is directed to a lamination system useful in the manufacture of circuitized substrates. The lamination system comprises a dry film photoresist and a laminate substrate comprising a metal (e.g., copper or stainless steel) or non-metal surface. The lamination processes of the present invention further comprise a lamination fluid comprising water and a surface energy modification agent.

### DETAILED DESCRIPTION OF THE PREFERRED EMBODIMENT(S)

In one embodiment of the present invention, a dry film photoresist is applied to the copper surface of a copper laminate, using a conventional or non-conventional wet lamination process. During the wet lamination process, a wet lamination fluid is applied between the photoresist dry film and the substrate surface. The wet lamination fluid is intended to fill any irregularities of the surfaces of the two layers being laminated together, thereby inhibiting air entrapment between the two layers. Thereafter, the wet lamination fluid can be volatilized away or otherwise removed.

The wet lamination fluids of the present invention are water based and are up to 50, 60, 70, 80, 90, 95, 96, 97, 98, 99, 99.5 or 99.9 weight percent water. In one embodiment, prior to incorporation into the lamination fluid, the water component: 1. is sufficiently free of unwanted to ionic species to have an electrical resistivity of at least 10⁰, 10¹, 10², 10³, 10⁴, 10⁵, 10⁶, 10⁷, 10⁸ or 10⁹ Ohms; and 2. contains dissolved oxygen in an amount less than 15, 14, 12, 11, 10, 9, 8, 7, 6, 5, 4, 3, 2, 1, or 0.1 parts per million.

In accordance with the present invention, the wet lamination fluids of the present invention comprise at least one surface energy modification agent. In one embodiment, the surface energy modification agent is one or more of the following:
1. an organic alcohol;
2. an organic phosphate ester;
3. a fluoro alcohol, such as:

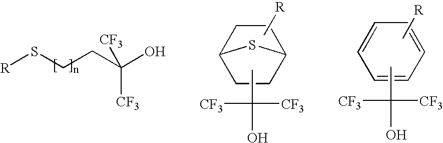

where R is hydrogen, an alkyl group and n is a positive integer up to 25.
4. anionic surfactant, such as, surfactants based upon sulfate, sulfonate or carboxylate anions, including:
   a. sodium dodecyl sulfate (SDS),
   b. sodium laureth sulfate (sodium lauryl ether sulfate),
   c. ammonium lauryl sulfate, and
   d. alkyl benzene sulfonate,
   e. fatty acid salts,
   f. sodium dodecyl sulfate (SDS), ammonium lauryl sulfate, and other alkyl sulfate salts
5. cationic surfactants, such as:
   a. cetyl trimethylammonium bromide (CTAB) a.k.a. hexadecyl trimethyl ammonium bromide, and other alkyltrimethylammonium salts
   b. cetylpyridinium chloride (CPC)
   c. polyethoxylated tallow amine (POEA)
   d. benzalkonium chloride (BAC)
   e. benzethonium chloride (BZT)
6. zwitterionic (amphoteric) surfactants, such as:
   a. dodecyl betaine
   b. dodecyl dimethylamine oxide
   c. cocamidopropyl betaine
   d. coco ampho glycinate, and
7. nonionic surfactant, such as:
   a. alkyl poly(ethylene oxide),
   b. copolymers of poly(ethylene oxide) and poly(propylene oxide) (commercially called Poloxamers or Poloxamines)
   c. alkyl polyglucosides, including:
      a. octyl glucoside
      b. decyl maltoside
   d. fatty alcohols, including:
      a. cetyl alcohol
      b. oleyl alcohol, and
   e. cocamide, and
8. ether, such as:
   a. glycol ether, including: ethylene glycol monodibutyl ether, ethylene glycol monophenyl ether (phenyl glycol), diethylene glycol monoethyl ether, diethylene glycol monomethyl ether, diethylene glycol monobutyl ether, diethylene glycol dibutyl ether, diethylene glycol monophenyl ether, propylene glycol monobutyl ether, propylene glycol monophenyl ether, dipropylene glycol monomethyl ether, dipropylene glycol monoethyl ether, dipropylene glycol monobutyl ether, dipropylene glycol monophenyl ether, tripropylene glycol monomethyl ether, tripropylene glycol monoethyl ether, and diethylene glycol monoethyl ether acetate,
b. derivative of glycol ether, including: propylene glycol monomethyl ether acetate, and propylene glycol diacetate.

In one embodiment, the surfactant agent is present in amounts in a range between (and optionally including) 0.0001, 0.001, 0.005, 0.01, 0.02, 0.05, 0.08, 0.1, 0.2, 0.3, 0.4, 0.5, 0.6, 0.7, 0.8, 0.9, 1.0, 2.0, 3.0 and 4.0 moles/liter. In general, the amount of surfactant that may be used should be sufficient to achieve effective surface wetting of the photoresist dry film, and this will typically vary depending on the particular surfactant selected and the nature of the surface of the dry film photoresist. However, too much surfactant may result in undesirable foaming and/or flocculation during the lamination process. In one embodiment, an anti-foaming agent is included to ensure that no unwanted foaming occurs during lamination.

In one embodiment, the pH of the fluid is also generally controlled, for instance, by the addition of a basic compound such as sodium hydroxide or potassium hydroxide in the desired amount of achieve the optimized pH. In one embodiment, it is desirable to maintain the pH of the lamination fluid of this invention within a range between (and optionally including) any two of the following: 1.0, 2.0, 3.0, 4.0, 5.0, 6.0, 7.0, 8.0, 9.0, 10.0, 11.0, and 12.0. The pH of the lamination fluid of this invention may be adjusted using any known acid, base, or amine, particularly an acid or base that contains no metal ions, such as ammonium hydroxide and amines, or nitric, phosphoric, sulfuric, or organic acids to avoid introducing undesirable metal components into the process.

In one embodiment, the surface energy modification agent is present in an amount in a range between 0.0001 and 3.0 moles/liter, and the pH of the fluid is between 3 and 11.

In one embodiment the lamination fluid of the present invention includes a complexing agent. Useful complexing agents include, but are not limited to, acids such as citric, lactic, malonic, tartaric, succinic, acetic, oxalic, and other acids, as well as amino acid and amino sulfuric acids, phosphoric acids, phosphonic acids, and their salts. The complexing agent can be present in an amount between (and optionally including) any two of the following: 0.1, 0.2, 0.5, 0.7, 1.0, 2.0, 3.0, 4.0, 5.0, 6.0, 7.0, 8.0, 9.0, and 10.

In another embodiment, the lamination fluid comprises an organic amino compound. Useful organic amino compounds include alkylamines, alcohol amines, amino acids, urea, derivatives of urea, and mixtures thereof. Preferred organic amino compounds are long chain alkylamines and alcoholamines. The term “long chain alkylamines” refers to alkylamines having from 7 to 12 or more carbon atoms including, for example, nonylamine and dodecylamine. Examples of useful alcoholamines include, but are not limited to monoethanolamine, and triethanolamine. Examples of useful derivatives of urea include, but are not limited to biurea. A preferred organic amino compound is the long chain alklyamine, dodecylamine. A preferred alcoholamine is triethanolamine.

The organic amino compound can be present in an amount between (and optionally including) any two of the following: 0.1, 0.2, 0.5, 0.7, 1.0, 2.0, 3.0, 4.0, 5.0, 6.0, 7.0, 8.0, 9.0, and 10 weight percent.

In one embodiment, the lamination fluid of the present invention includes a film forming agent. Useful film forming agents are nitrogen containing cyclic compounds such as:
1. thiazoles, such as:
   a. imidazole,
   b. benzotriazole,
   c. benzimidazole,
   d. benzothiazole and
   e. 2-mercaptobenzothiazole;
   f. methylimidazole;
2. oxazoles, such as 4H-oxazol-5-one;
   3. benzopyrazoles, such as indazole; and
   4. mixtures thereof and their derivatives with hydroxy, amino, imino, carboxy, mercapto, nitro and alkyl substituted groups, as well as urea, thiourea and others.

The concentration of the film forming agent may vary over a relatively wide range, such as, in an amount between (and optionally including) any two of the following: 0.01, 0.02, 0.05, 0.07, 0.1, 0.2., 0.3., 0.4, 0.5, 0.6, 0.8, 0.9, 1.0, 2.0 and 3.0 weight percent.

In one embodiment, the film forming agent is benzotriazole (“BTA”). However, benzotriazole and substituted benzotriazoles tend to have very low solubilities in water, and to provide a sufficient concentration of a benzotriazole in aqueous solution, it is generally necessary to neutralize the benzotriazole with at least a molar equivalent of an oxidizing agent. (One mole of a non-acid oxidizing agent equivalent to one mole of benzotriazole.) Useful oxidizing agents for use in the lamination fluids of the present invention include oxidizing agents comprising one or more inorganic or organic per-compounds. A per-compound as defined by Hawley's Condensed Chemical Dictionary is a compound containing at least one peroxy group (—O—O—) or a compound containing an element in its highest oxidation state. Examples of compounds containing at least one peroxy group include, but are not limited to, hydrogen peroxide and its adducts such as urea hydrogen peroxide and percarbonates, organic peroxides such as benzyl peroxide, peracetic acid, and di-t-butyl peroxide, monopersulfates (SO5⁼), dipersulfates (S₂ O₈⁼), and sodium peroxide.

Examples of compounds containing an element in its highest oxidation state include, but are not limited, to periodic acid, periodate salts, perbromic acid, perbromate salts, perchloric acid, perchloric salts, perboric acid, and perborate salts and permanganates. Examples of non-per compounds that meet the electrochemical potential requirements include but are not limited to bromates, chlorates, chromates, iodates, iodic acid, and cerium (IV) compounds such as ammonium cerium nitrate.

Preferred oxidizing agents are peracetic acid, urea-hydrogen peroxide, hydrogen peroxide, monopersulfuric acid, dipersulfuric acid, salts thereof, and mixtures thereof including mixtures of urea and hydrogen peroxide.

The oxidizing agent may be present in an amount between (and optionally including) any two of the following: 0.3, 0.5, 0.8, 1.0, 2.0, 3.0, 4.0, 5.0, 6.0, 7.0, 8.0, 9.0, 10, 12, 14, 15, 16, 17, 18, 19, 20, 25 and 30 weight percent.

In addition to water, the wet lamination fluids of the present invention can comprise a co-solvent, such as:
1. an alcohol, such as:
   a. isopropanol,
   b. 2-butoxy-ethanol-1,
   c. isobutanol, and
   d. 1. propanol
2. a ketone, such as
   a. methyl isobutyl ketone, and
   b. isophorone,
3. a hydrocarbon solvent, such as
   a. benzene
   b. C₅₋₁₀ paraffins

The non-aqueous co-solvent can be present in an amount between (and optionally including) any two of the following: 0.1, .0.5, 1, 2, 3, 4, 5, 6, 7, 8, 9, 10, 12, 15 or 20 weight percent. The presence of the non-aqueous cosolvent facilitates wetting of the photoresist dry film surface.

### EXAMPLES

Lab tests were conducted and results were obtained as follows.
1. Dry film photoresist called “MX Advance 115” was applied on a stainless steel surface with 3 different types of lamination conditions (Dry Lam=conventional, Wet Lam=DI water was used and Wet Lam-S with organic alcohol as additive to DI water).

The following isolated line resolution chart was obtained.
Significant improvement can be observed on dry film adhesion when this new fluid technology was used.
2. Dry film photoresist called “MX-5040” was applied on a copper surface which containing some amount of antitarnish. Again Wet Lam-S was able to show some improvement in terms of isolated lines resolution capability as below resolution charts. Additionally both Wet Lam and Wet Lam-S provided excellent image quality without dry film lifting (see photo 1 below).

The above discussion of the present invention is intended to be merely illustrative and therefore non-limiting. Any limitations to the present invention are intended to be provided solely by the following claims.

What is claimed is:

1. A lamination system comprising:
A. a dry film photoresist,
B. a substrate having a surface, and
C. a lamination fluid comprising:
i. water; and
ii. a surface energy modification agent

2. A lamination system in accordance with claim 1, wherein said surface energy modification agent comprises one or more of the following:
a. an organic alcohol
b. an organic phosphate ester;
c. a fluoro alcohol,
d. an ionic surfactant,
e. a cationic surfactant,
f. a zwitterionic (amphoteric) surfactant, and
g. a nonionic surfactant, and
h. an ether

3. A lamination system in accordance with claim 1, wherein the lamination fluid further comprises a complexing agent in an amount between 0.1 and 10 weight percent.

4. A lamination system in accordance with claim 1, wherein the lamination fluid further comprises an organic amino compound in an amount between 0.1 and 10 weight percent.

5. A lamination system in accordance with claim 1, wherein the lamination fluid further comprises a film forming agent in an amount between 0.01 and 3 weight percent.

6. A lamination system in accordance with claim 4, wherein the film forming agent is benzotriazole or a substituted benzotriazole neutralized with at least a molar equivalent of an oxidizing agent, the oxidizing agent being an inorganic or organic per-compound.
